(19) United States
(12) Patent Application Publication
(10) Pub. No.: US 2008/0098282 A1
(43) Pub. Date: Apr. 24, 2008

(54) HIGH SPEED ERROR CORRECTING SYSTEM

(76) Inventor: Kuo-Lung Chien, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/551,251

(22) Filed: Oct. 20, 2006

(51) Int. Cl. G11C 29/00

(52) U.S. Cl. 714/769

(57) ABSTRACT

Disclosed is an error correcting system, which comprises: a demodulator, for receiving and demodulating data from the optical disc to generate input data; a data buffer, for storing the input data; an on the fly ECC decoder, for performing a PI error correction to the input data before the input data from the demodulator stored by the buffer; an ECC decoder, for performing an error correction on the input data in the data buffer to generate an error correction information and correcting the input data to transform it to corrected data; an non-linear EDC check device, for performing a non linear error detection on the input data to generate a first EDC result stored by the EDC memory; an EDC corrector, for adjusting the first EDC result according to the error correction information; wherein the ECC decoder first performs a PO error correction on the input data.

### BACKGROUND OF THE INVENTION

The present invention relates to an error correcting module, and more particularly relates to an error correcting module for an optical disc drive.

In data storage systems, error correction mechanisms play an important role in improving the accuracy of data. For example, symbols read from an optical medium are typically arranged into a block format for decoding according to industry standard optical storage techniques. FIG. 1 shows a typical ECC block 100 of an industry standard digital versatile disc (DVD) or a high definition DVD (HD-DVD). As illustrated, the symbols in the ECC block 100 are arranged into 208 rows by 182 columns. Each row of the ECC block 100 has ten symbols for providing so-called inner parity (PI). For example, symbols B0,172 through B0,181 are the inner parity of the first row of the ECC block 100. In addition, sixteen rows of the ECC block 100 are provided for so-called outer parity (PO). For example, symbols B192,0 through B207,0 are the outer parity of the fist column of the ECC block 100. The 16 rows of outer parity are interleaved with 192 data rows; that is, there is 1 row of outer parity after each set of 12 data rows.

FIG. 2 is a block diagram of a related art error correction system 200. The system 200 includes an optical disc 201, a demodulator 203, a PI direction ECC decoder 205, a PO direction ECC decoder 207, an EDC circuit 209, a decision circuit 211, a bus 213 and a data buffer 215. The data read from the optical disc 201 is processed by the demodulator 203 to form the ECC blocks shown in FIG. 1, and the ECC blocks are stored in the data buffer 215 through the bus 213. The PI direction ECC decoder 205 performs a PI error correction according to the syndrome generated from PI; that is, the PI direction ECC decoder 205 detects the error location in the data and amends the error in the PI direction (horizontal direction). The PO direction ECC decoder 207 performs a PO error correction according to the syndrome generated from PO; that is, the PO ECC decoder 205 detects the error location in the data and amends the error in the PO direction (vertical direction). The PI ECC correction and the PO ECC correction are alternatively performed until the number of repeating of the ECC operation reaches a predetermined number or no any further correction is needed.

Next, the EDC circuit 209 detects the data processed by the PI direction ECC decoder 205 and the PO direction ECC decoder 207 to generate an EDC result, and the decision circuit 211 is used for checking the following objects: checking if the number of the repeating of ECC operation reaches a predetermined number, checking if any further correction is needed, checking if the final EDC result=0.

Although the cost of the system 200 is low, it requires a large amount of bandwidth. Furthermore, the EDC circuit 209 detects the data processed by the PI direction ECC decoder 205 and the PO direction ECC decoder 207 after the whole ECC block is processed, thus the speed of the system 200 is slow. Accordingly, the system 200 is not suitable for high speed processing.

FIG. 3 is a block diagram of a related art error correction system 300. In the system 300, the EDC operation is only performed on the data that is processed by the PI error correction. As shown in FIG. 3, the system 300 includes an optical disc 301, a demodulator 303, a PO direction ECC decoder 304, a PI direction ECC decoder 305, a memory device 307, a linear EDC circuit 309, a decision circuit 310, a bus 311 and a data buffer 313. As in the system 200, the data read from the optical disc 301 is processed to form input data with ECC blocks. The PO direction ECC decoder 304 performs a PO error correction on the input data. The PI direction ECC decoder 305 performs a PI ECC correction on part of the input data. Also, the same part of the input data is stored in the memory device 307 and an “XOR” operation is performed on the same part of the input data stored in the memory device 307 and the part of the input data processed by the PI direction ECC decoder 305 to form data G. Thus, the capacity of the memory device 307 is at least one row. The linear EDC circuit 309 detects the G data to generate an EDC result, and the decision circuit 310 determines the next step of the system according to the EDC result.

Although the cost of the system 300 is low and the speed is faster than the system 200, it still requires a large amount of bandwidth. Thus this system is also not ideal. Also, the speed of the related art shown in FIG. 3 is faster than the related art shown in FIG. 2, but the related art shown in FIG. 3 is still not fast enough for high speed decoding system, however.

FIG. 4 is a block diagram of a related art error correction system 400 disclosed in U.S. Pat. No. 6,772,385B2. The system 400 includes a PI direction ECC decoder 405, a linear EDC check 407, an EDC memory 409, a PO direction ECC decoder 411, a PO direction EDC corrector 413 and a decision circuit 419. For brevity, parts of the system 400 that are the same as system 300 are not illustrated. The PI direction ECC decoder 405 is used for performing a Pi error correction on the data, and the PO direction ECC decoder 411 is used for performing a PO error correction on the data. The linear EDC check 407 is used for performing PI error detection on the corrected data from the PI direction ECC decoder 405, and the PO direction EDC corrector 413 is used for performing PO error detection on the corrected data from the PO direction ECC decoder 411. The difference between the linear EDC check 407 and the PO direction EDC corrector 413 is that the linear EDC check 407 detects all data in an ECC block, but the PO direction EDC corrector 413 only detects part of the data in an ECC block which has been corrected in PO direction ECC decoder 411. The EDC results from the linear EDC check 407 and the PO direction EDC corrector 413 are then merged to a final EDC result, the final EDC result is stored in the EDC memory 409, and the decision circuit 419 decides the next step of the system 400 according to the final EDC result.

The speed of the system 400 is faster than the previous related art and is suitable for a high speed decoding system. However, in the system 400, PI ECC decoder 405 and PO ECC decoder 411 will not start until the data buffering is finished. Therefore, the efficiency of the final EDC result generation is not ideal.

FIG. 5 is a block diagram of a related art error correction system 500 disclosed in U.S. Pat. No. 6,003,151. The system includes a demodulator 503, an PI direction EDC check device 505, a memory device 507, an on the fly PI direction ECC decoder 509, a PO direction ECC decoder 511, an EDC memory 513, a PO direction EDC corrector 515, a bus 516, and a data buffer 517. The memory device 507 stores the few rows data of ECC blocks from the demodulator 503, and then the on the fly ECC decoder 509 performs a PI error correction operation on the data stored in the memory device 507. The on the fly EDC check 505 performs an PI EDC to detect the corrected data processed by the PI direction ECC decoder 509 to generate an EDC result, and the first EDC result is stored in the data buffer 517. The first EDC result is read and stored to the EDC memory 513, the PO direction ECC decoder 511 then performs a PO error correction operation on the data stored in the data buffer 517, and the PO direction EDC corrector 515 detects the error part of the data processed by the PO direction ECC decoder 511 to amend the EDC result stored in the EDC memory 513. The decision circuit 519 is used to determine the next step of the system 500 according to the EDC result stored in the EDC memory 513. Since the on the fly ECC and on the fly EDC are utilized, the speed of the related art shown in FIG. 5 is faster than the related art shown in FIG. 4, but the related art shown in FIG. 5 needs a memory device for overcoming the on the fly EDC calculation. Besides, the error correction system 500 shown in FIG. 5 hardly solve the problems of longer frame sync shift because the data input of the on the fly EDC device must come from the memory device. Therefore the frame sync shift adjustment capability totally depends on the size of the memory device, which leads to the increase of cost.

Therefore, a new system and method that overcomes the problems of the related art is needed.

### SUMMARY OF THE INVENTION

One objective of the present invention is to provide an error correcting module which requires less storage space but gets higher speed and better performance especially on serious frame sync shift.

The disclosed embodiment discloses an error correcting system, which comprises: a demodulator, for receiving and demodulating data from the optical disc to generate input data; a data buffer, for storing the input data; an on the fly ECC decoder, for performing a Pi error correction to the input data before the input data from the demodulator stored by the buffer; an ECC decoder, for performing an error correction on the input data in the data buffer to generate an error correction information and correcting the input data to transform it to corrected data; an non-linear EDC check device, for performing a non linear error detection on the input data to generate a first EDC result stored by the EDC memory; an EDC corrector, for adjusting the first EDC result according to the error correction information; wherein the ECC decoder first performs a PO error correction on the input data. The disclosed embodiment discloses an error correcting method for correcting errors in data from an optical disc. The method comprises: (a) receiving and demodulating data from the optical disc to generate input data; (b) storing the input data from the step (a); (c) performing a PI error correction on the input data before the input data is stored; (d) performing an error correction on the input data in the data buffer to generate an error correction information, correcting the data in the data buffer to transform the input data to corrected data;(e) performing a non linear error detection on the input data to generate a first EDC result;(f) storing the EDC result; and(g) adjusting the EDC result according to the error correction information; wherein the step (c) performs a PO error correction on the input data first.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a typical ECC block of an industry standard digital versatile disc (DVD) or a high definition DVD (HD-DVD).

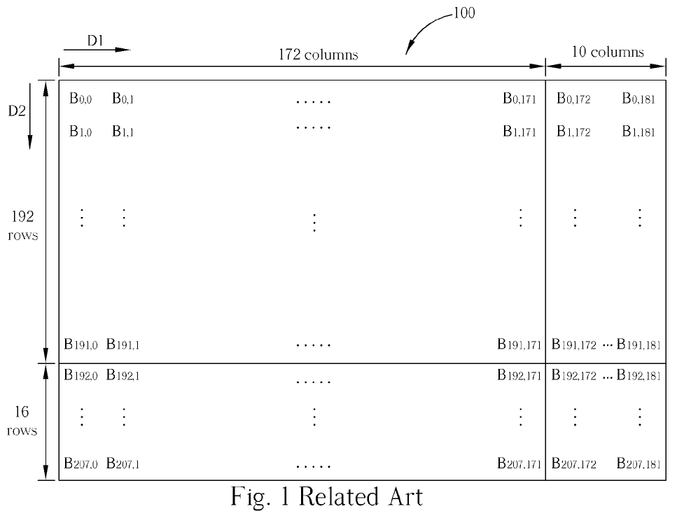

FIG. 2 is a block diagram of a related art error correction system.

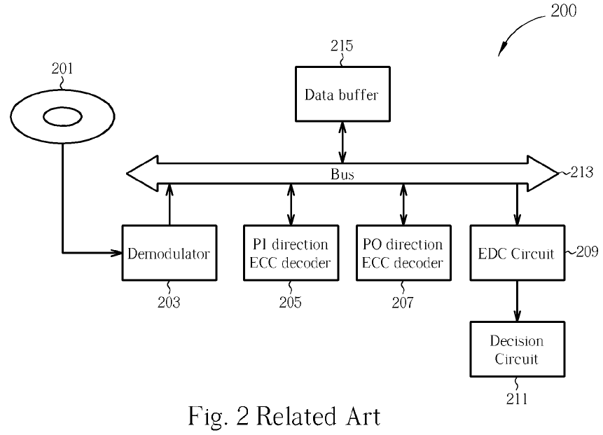

FIG. 3 is a block diagram of a related art error correction system.

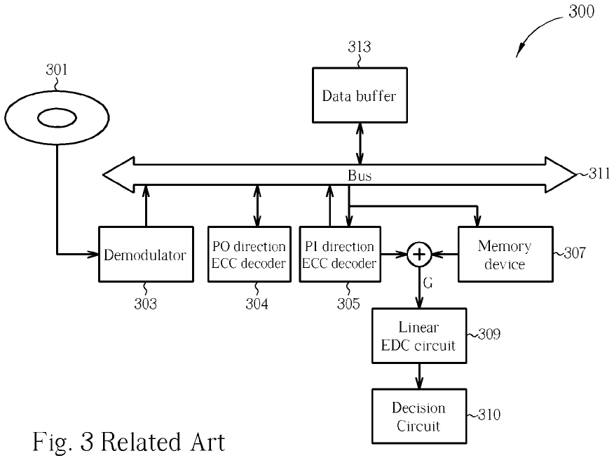

FIG. 4 is a block diagram of related art error correction system disclosed in U.S. Pat. No. 6,772,385B2.

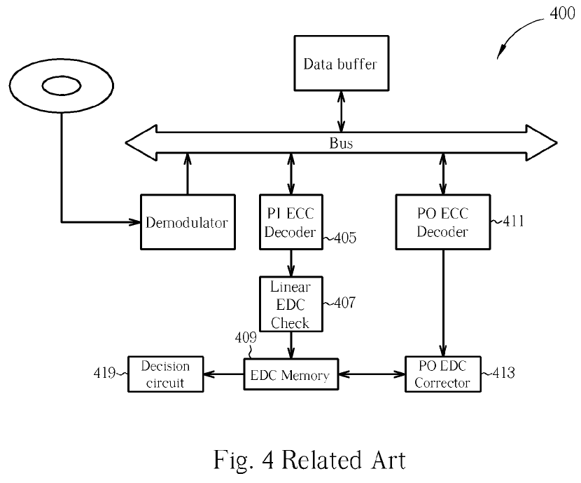

FIG. 5 is a block diagram of related art error correction system disclosed in U.S. Pat. No. 6,003,151.

FIG. 6 is a block diagram illustrating an error correcting system for correcting errors in data from an optical disc according to a preferred embodiment of the present invention.

FIG. 7 is a block diagram illustrating the detailed structures of the EDC check device shown in FIG. 6.

FIG. 8 is a block diagram illustrating the detailed structures of the EDC check device shown in FIG. 6.

FIG. 9 is a flow chart illustrating the operation of the systems shown in FIG. 7 and FIG. 8.

FIG. 10 is a flow chart illustrating an error correcting method for correcting errors in data from an optical disc corresponding to the systems shown in FIG. 7 and FIG. 8.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

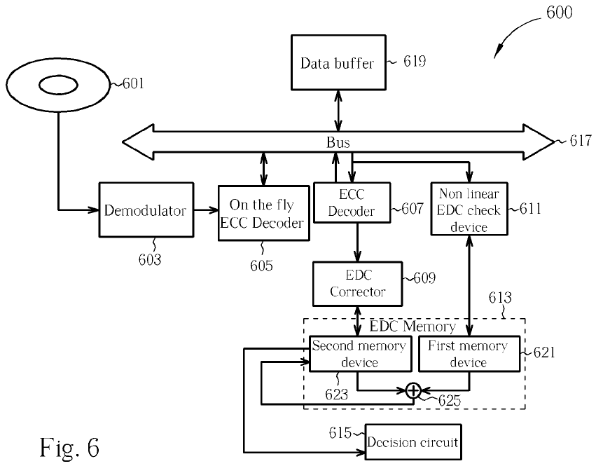

FIG. 6 is a block diagram illustrating an error correcting system 600 for correcting errors in data from an optical disc according to a preferred embodiment of the present invention. The system 600 includes a demodulator 603, an on the fly ECC decoder 605, an ECC decoder 607, an EDC corrector 609, an non-linear EDC check device 611, an EDC memory 613, a decision circuit 615, a bus 617, and a data buffer 619.

The demodulator 603 is used for receiving and demodulating data from the optical disc 601 to generate input data. The on the fly ECC decoder 605 performs an on the fly Pi ECC operation to the input data, that is, performs a PI ECC operation before the input data is stored on the data buffer 619. The ECC decoder 607 is used for performing an error correction on the input data in the data buffer 619 to generate an error correction information and correcting the data in the data buffer 619 to transform the input data to corrected data. The data buffer 619, which is coupled to the demodulator 603, is used for storing the input data from the demodulator 603. The non-linear EDC check device 611 is used for performing an error detection on the input data to generate a first EDC result. The EDC memory 613, which is coupled to the non-linear EDC check device 611, is used for storing the first EDC result. The EDC corrector 609, which is coupled to the ECC decoder 607 and the EDC memory 613, is used for adjusting the first EDC result according to the error correction information in order to generate a final EDC result. It should be noted that the ECC decoder 607 performs a PO error correction on the input data first. The decision circuit 615 is used for determining the next step of the system 600 according to the final EDC result stored in the EDC memory.

Also, the EDC memory 613 of this embodiment can further comprise a first memory device 621, a second memory device 623, and a computing unit 625. In this case, the EDC corrector 609 detects the error parts of the corrected data from ECC decoder 607 to generate an error corrected EDC result, and the non-linear EDC check device 611 detects the input data to generate a first EDC result. The computing unit 625 performs a “XOR” operation on the first EDC result and the error corrected EDC result to generate a final EDC result. The decision circuit 615 is used for determining the next step of the system 600 according to the final EDC result stored in the EDC memory 613.

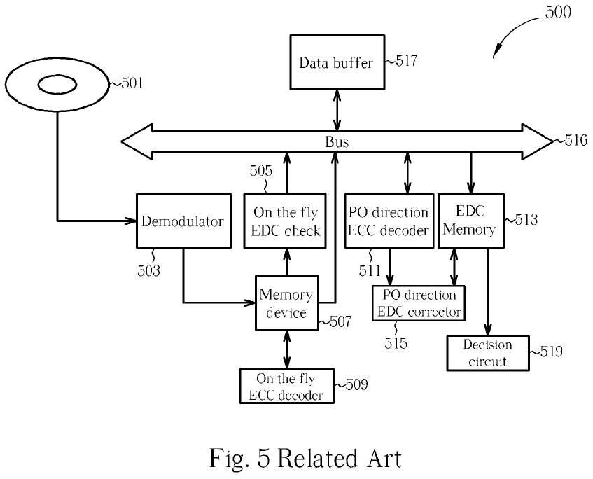

Comparing with the prior art shown in FIG. 5, since the non-linear EDC device replaces the on the fly EDC device, the error correcting system 600 shown in FIG. 6 can operate without using memory device and can solve the problems of longer frame sync shift. Therefore, the input data of non-linear EDC device is from data buffer, and the frame sync shift adjustment capability is not limited. Furthermore, the error correcting system 600 can omit the memory device 507 to reduce the cost.

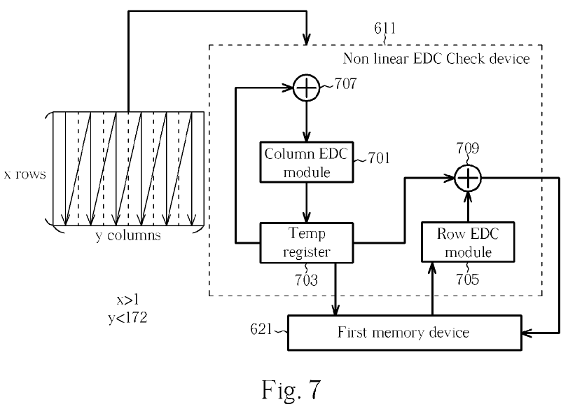

FIG. 7 is a block diagram illustrating the detailed structure of the non-linear EDC check device 611 shown in FIG. 6, and also illustrates the non-linear EDC operation of the non-linear EDC check device 611. It should be noted that the detailed structure and operation shown in FIG. 7 are only an example of the non-linear EDC check device 611, and should not be taken as limiting the scope of the present invention. Persons skilled in the art can easily use other structures and operations to achieve the function of the example shown in FIG. 7.

The non-linear EDC check device 611 shown in FIG. 7 includes a column EDC module 701, a temp register 703, a row EDC module 705, and two computing units 707 and 709, wherein the temp register 703, the row EDC module 705 and the computing unit 709 are coupled to the first memory device 621. The column EDC module 701 is used for performing an error detection on the symbols of input data in a vertical direction, and the result of the detection is stored to the temp register 703. The previous EDC result from the first memory device 621 is inputted to the row EDC module 705, which is used when the error detection of one partial column, is finished and the error detection is going to be performed on the other column to generate the non-linear EDC result and construct the first EDC result when whole sector data inputted to the non-linear EDC check device. In this case, the length of each column is longer than one byte.

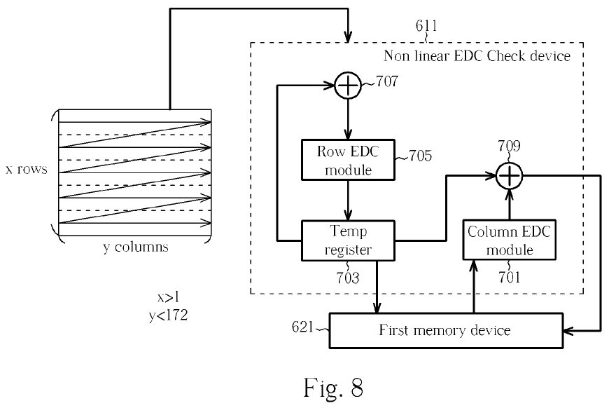

Besides, the row EDC and the column EDC can be reversed, as shown in FIG. 8. In FIG. 8, the location of the column EDC module 701 and the row EDC module 705 are exchanged. The row EDC module 705 is used for performing an error detection on the symbols of input data in a horizontal direction, and the result of the detection is stored to the temp register 703. The previous EDC result from the first memory device 621 is inputted to the column EDC module 701, which is used when the error detection of one partial row, is finished and the error detection is going to be performed on the other row to generate the non-linear EDC result and construct the first EDC result when whole sector data inputted to the non-linear EDC check device. In the structure of FIG. 8, the length of one row cannot be over 172 bytes or the column EDC module 705 will not work, however.

In short, the non-linear operation of the non-linear EDC check device 611 means the EDC operation is performed following the arrow direction shown in FIG. 7 or FIG. 8. Also, the detail operations and structures of FIG. 7 and FIG. 8 have been disclosed in another patent having application Ser. No. 11/162,278, which is applied by the same assignee.

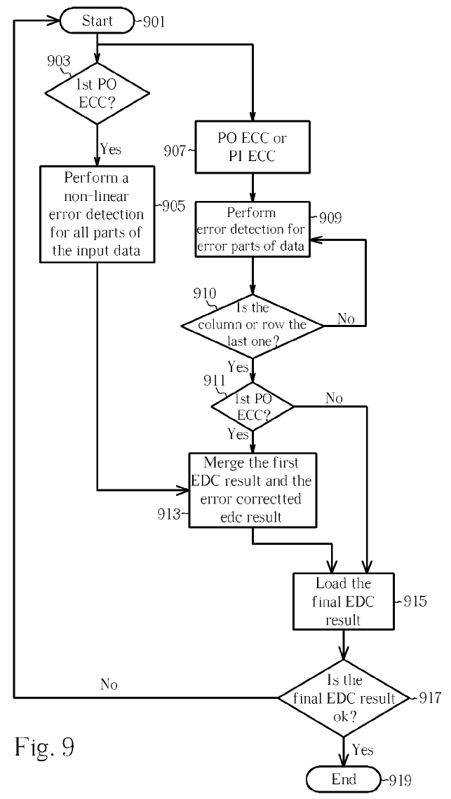

FIG. 9 is a flow chart illustrating the operation of the systems shown in FIG. 6, FIG. 7 and FIG. 8. Please note the flow chart is only used to explain the preferred operation of the systems shown in the FIG. 6, FIG. 7 and FIG. 8, and is not meant to limit the scope of the present invention. The steps are described as below:

Step 901:

Start error correction and detection

Step 903:

Check if the error correction performed by the ECC decoder 607 is a first PO error correction or not. If yes, concurrently perform step 905, step 907 and then the steps following the step 907.

Step 905:

Use the non-linear EDC check device 611 to perform a non-linear error detection for all parts of the input data to generate a first EDC result.

Step 907:

Use the ECC decoder 607 to perform a PO error correction or a PI error correction according to the result from step 917 in order to generate corrected data.

Step 909:

The EDC corrector 609 performs error detection on corrected parts of the corrected data to generate an error corrected EDC result.

Step 910:

Check if the processed column or row is the last one or not. If yes, go to the step 911. If no, go back to the step 909.

Step 911:

Check if the PO error correction is the first PO error correction. If yes, go to step 913. If no, go to step 915.

Step 913:

Merge the first EDC result from step 905 and the error corrected EDC result from step 909.

Step 915:

Load the final EDC result.

Step 917:

Determine if the loop should be restarted or not according to the final EDC result. If the final EDC result is OK, the error connection and detection loop is ended. Otherwise, the error connection and detection loop will be restarted again.

If the optical disc shown in FIG. 5 and FIG. 6 is an HD-DVD, the operation is a little different from that shown in FIG. 9. As is well known, an HD-DVD includes more sectors than a DVD. Thus, if the non-liner EDC check device 611 is used for processing an HD-DVD, the sectors of the HD-DVD are separated in different kinds of ECC blocks, and the non-linear EDC check device 611 performs error detection on the ECC blocks, respectively. The error detection results are merged to generate a first EDC result.

For example, the sectors can be classified into even sectors, which are composed of even rows of a sector and odd sectors which are composed of odd rows of a sector, where each ECC block is composed of even sectors and odd sectors alternately. Also, the EDC memory size of the first EDC result and error corrected EDC result are increased. Since persons skilled in the art know the detailed operation of error detection operation for HD-DVD, the description is omitted for brevity.

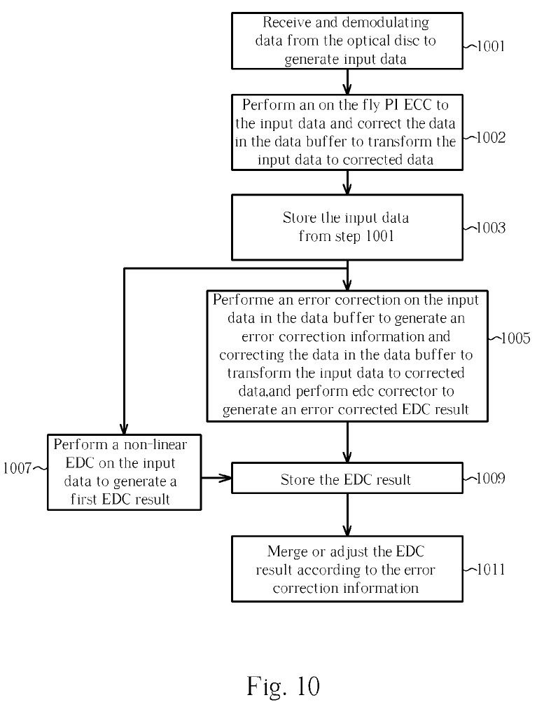

FIG. 10 is a flow chart illustrating an error correcting method for correcting errors in data from an optical disc corresponding to the systems shown in FIG. 6, FIG. 7 and FIG. 8. The error correcting method for correcting errors in data from an optical disc includes the following steps:

Step 1001:

Receive and demodulate data from the optical disc to generate input data.

Step 1002:

Perform an on the fly PI error correction to the input data and correct the data in the data buffer to transform the input data to corrected data. That is, performing a PI error correction before the input data is stored.

Step 1003:

Store the input data from step 1001.

Step 1005:

Perform an error correction on the input data in the data buffer to generate an error correction information, correct the data in the data buffer to transform the input data to corrected data

Step 1007:

Perform non-linear error detection on the input data to generate a first EDC result.

Step 1009:

Store the EDC result.

Step 1011:

Merge or adjust the EDC result according to the error correction information.

The step 1005 performs a PO error correction on the input data first while the input data is processed.

According to above-mentioned description, since the PO direction EDC is used, the system and the method according to the present invention not only provides operation as quick as the related art described in FIG. 5 but also need no memory devices for buffering the calculation of on the fly EDC. Thus the cost and circuit area is decreased.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An error correcting system for correcting errors in data from an optical disc, comprising:
a demodulator, for receiving and demodulating data from the optical disc to generate input data;
a data buffer, coupled to the demodulator, for storing the input data;
an on the fly ECC decoder, coupled to the demodulator and the buffer, for performing a PI error correction to the input data before the input data from the demodulator stored by the buffer;
an ECC decoder, coupled to the data buffer, for performing an error correction on the input data in the data buffer to generate an error correction information and correcting the data in the data buffer to transform the input data to corrected data;
an non-linear EDC check device, for performing a non linear error detection on the input data to generate a first EDC result;
an EDC memory, coupled to the non-linear EDC check device, for storing the first EDC result; and
an EDC corrector, coupled to the ECC decoder and the EDC memory, for adjusting the first EDC result according to the error correction information to generate a final EDC result;
wherein the ECC decoder first performs a PO error correction on the input data.

2. The error correcting system of claim 1, wherein the ECC decoder alternately performs a PO error correction and a PI error correction on the input data until the final EDC result associated with the input data is equal to a predetermined value.

3. The error correcting system of claim 1, further comprising a decision circuit, coupled to the EDC memory, for deciding whether the input data should be outputted or not according to the final EDC result stored in the EDC memory.

4. The error correcting module of claim 1, wherein the EDC corrector is used for performing an error detection on the error parts of the corrected data to get an error corrected EDC result, and the EDC memory comprises:
a first memory device for storing the first EDC result from the non-linear EDC check device;
a second memory device for storing the error corrected EDC result from the EDC corrector; and
a computing unit, coupled to the first memory device and the second memory device to perform a calculating operation for the error corrected EDC result and the first EDC result to generate the final EDC result.

5. The error correcting module of claim 1, wherein the column length of the input data is longer than one byte and the EDC check device includes:
a column EDC module, for detecting errors for symbols of the input data in columns; and
a row EDC module, for performing a column changing operation while the operation of the column EDC module is changed from one column to another column.

6. The error correcting module of claim 1, wherein the row length of the input data is smaller than 172 bytes and the EDC check device includes:
a row EDC module, for detecting errors for symbols of the input data in rows; and
a column EDC module, for performing a row changing operation while the operation of the row EDC module is changed from one row to another row.

7. The error correcting module of claim 1, wherein when the input data is from an HD-DVD, the input data is separated in different kinds of ECC blocks, and the non-linear EDC check device performs the error detection on the different kinds of ECC blocks respectively to generate detecting results and merge the detecting results to generate the first EDC result.

8. An error correcting method for correcting errors in data from an optical disc, comprising:
(a) receiving and demodulating data from the optical disc to generate input data;
(b) storing the input data from the step (a);
(c) performing a PI error correction on the input data before the input data is stored;
(d) performing an error correction on the input data in the data buffer to generate an error correction information, correcting the data in the data buffer to transform the input data to corrected data;
(e) performing a non linear error detection on the input data to generate a first EDC result;
(f) storing the first EDC result; and
(g) adjusting the first EDC result according to the error correction information.

9. The error correcting method of claim 8, wherein the step (b) alternately performs a PO error correction and a PI error correction on the input data until the final EDC result associated with the input data is equal to a predetermined value.

10. The error correcting method of claim 8, further comprising deciding whether the input data should be outputted or not according to the EDC result.

11. The error correcting method of claim 8, wherein the column length of the input data is longer than one byte and the non-linear EDC check device includes:
detecting errors for symbols of the input data in columns; and
performing a column changing operation where the operation of the column EDC module is changed from one column to another column.

12. The error correcting module of claim 8, wherein the row length of the input data is smaller than 172 bytes and the non-linear EDC check device includes:
detecting errors for symbols of the input data in rows; and
performing a row changing operation while the operation of the row EDC module is changed from one row to another row.

13. The error correcting method of claim 8, wherein when the input data is from an HD-DVD, the input data is separated in different kinds of ECC blocks, and the non-linear EDC check device performs the error detection on the different kinds of ECC blocks respectively to generate detecting results and merge the detecting results to generate the EDC result.

14. The error correcting method of claim 8, further comprising:
performing an error corrected EDC according to the error correction information to generate an error corrected EDC result;
storing the error corrected EDC result;
storing the first EDC result from the step (e); and
performing a calculating operation for the error corrected EDC result and the first EDC result to generate the final EDC result.
